(19) United States
(12) Patent Application Publication
(10) Pub. No.: US 2009/0113269 A1
(43) Pub. Date: Apr. 30, 2009

(54) DATA DESCRAMBLING APPARATUS AND DATA DESCRAMBLING METHOD

(76) Inventor: Daigo Senoo, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/088,126

(22) PCT Filed: Sep. 25, 2006
(86) PCT No.: PCT/JP2006/318982

§ 371 Date: Mar. 26, 2008

(30) Foreign Application Priority Data
Sep. 26, 2005 (JP) 2005-278603

(51) Int. Cl. H03M 13/05; G06F 11/07

(52) U.S. Cl. 714/752; 714/E11.021

(57) ABSTRACT

When performing data descrambling for data including errors, a countermeasure against an error in a seed value that is required for the descrambling is realized in a system having no CPU.

There are provided an FIFO unit (202) in which data are stored, an error correction unit (205) for receiving the data contents from the FIFO unit and performing error detection, an ID holding register (204) for holding a seed that is needed for data descrambling or information that is needed for seed generation when the data contents are judged as correct data as a result of the error detection by the error correction unit, and a descrambling unit (203) for receiving the data from the FIFO and performing descrambling by using the value stored in the ID holding register. Therefore, it is possible to perform data descrambling even in a situation where a CPU cannot manage the seed value because the transfer data are used.

### TECHNICAL FIELD

The present invention belongs to a technical field relating to descrambling of data.

That is, the present invention relates to a data descrambling apparatus and a data descrambling method which are improved so as to accurately perform descrambling during transfer of data having a probability of including errors caused by noises or the like.

### BACKGROUND ART

A DVD (Digital Versatile Disk; hereinafter referred to as DVD) which is a kind of an optical disc will be described as a prior art.

Data recorded on a DVD (hereinafter referred to as DVD recorded data) have previously been scrambled, and a data format obtained after demodulation of the DVD recorded data is shown in FIG. 8.

The DVD recorded data reproduced from the optical disc are transferred as follows. Initially, ID (Identifier) information 801 of 4 bytes comprising upper 1 byte to which sector information is assigned and lower 3 bytes to which a sector number is assigned is transferred to a demodulation system of a DVD demodulation device. Subsequently, IED (ID Error Detection Code) information 802 comprising 2 bytes as parity information for the ID information 801 is transferred.

Subsequently, a reserve (hereinafter referred to as RSV) region 803 comprising 6 bytes is transferred, and data 804a comprising 160 bytes which are part of main data are transferred. Subsequently, as parity information for data corresponding to one row in the horizontal direction, i.e., as parity information for data of 172 bytes which comprise the ID information 801, the IED information 802, the RSV region 803, and the part 804a of the main data, a PI (Parity Inner) 805 comprising 10 bytes is transferred.

Next, a part 804b of the main data corresponding to the 161st byte to 332nd byte, which follows the part 804a of the main data, is transferred. As for this part of the main data, 172 bytes are transferred for each row, and a PI parity 805 comprising 10 bytes is also transferred for each row as parity information for the main data. This processing is repeated up to 11th row.

As for the 12th row, the main data of 168 bytes are transferred, and EDC (Error Detection Code) information 806 of 4 bytes which is error detection information for all of the ID information 801, the IED information 802, the RSV region 803, and the main data 804 is transferred. A PI parity 805 of 10 bytes is given to this row, and transferred in like manner as described above.

As for the 13th row, a PO (Parity Outer) 807 of 172 bytes is transferred as parity information in the vertical direction. A PI parity 805 of 10 bytes for the PO parity 807 is also given to this row, and transferred.

By the way, all of the IED information 802, the PI party 805, and the PO parity 806 are formed by Reed-Solomon codes (hereinafter also referred to as RS codes), and the IED has a correction capability of 2 bytes while the PI parity has a correction capability of 10 bytes in erasure correction.

Further, the main data 804 is subjected to data scrambling during recording.

This specification includes converting an ID comprising 4 bits in 1 byte among the 4 bytes constituting the ID information 801 into seed information on the basis of a table on which a predetermined conversion rule is described, i.e., a scrambling seed table, which is shown in FIG. 9, and subjecting the seed information to a predetermined operation, i.e., an EXOR (Exclusive OR) operation, thereby to convert it into scrambled data.

However, there is a probability that the above-mentioned ID information 801 might include an error due to disc noise or the like. Therefore, if descrambling is carried out using an incorrect seed value, the main data 804 becomes a completely unspecified value, i.e., an incorrect value.

A data descrambling apparatus which can avoid such drawback has already been developed by the inventors of the present invention. This conventional data descrambling apparatus is shown in FIG. 11.

In FIG. 11(a), a demodulation unit 1101 for demodulating data read out from a DVD disk outputs demodulated data 1111 as DVD data having the same format as described above. It is assumed that this DVD data 1111 has a probability of including random or burst error data due to noise, flaws on the disk, or the like.

An FIFO unit 1102 receives this data, and transfers post-FIFO data 1112 as the DVD data. A descrambling unit 1103 descrambles the DVD data 1112 according to the seed value, and transfers descrambled data 1113 as the DVD data to a main storage unit 1106.

The descrambling is performed by a shift register SRG and an exclusive OR circuit EXOR shown in FIG. 10. The shift register SRG receives the data of 15-bit length which is converted according to the scramble SEED table, and the exclusive OR circuit EXOR obtains an exclusive OR between the 10th-bit data and the 14th-bit data of the shift register SRG, and feedbacks the exclusive OR to the 0th bit to generate random digits, thereby performing descrambling.

That is, as shown in FIG. 11(b), a descrambling circuit 1103a comprises a shift register 1103a corresponding to the shift register SRG shown in FIG. 10, and an exclusive OR circuit 1103d corresponding to the exclusive OR circuit EXOR shown in FIG. 10.

An exclusive OR between the seed value outputted from the descrambling circuit 1103a and the DVD data 1112 outputted from the FIFO (First-In First-Out) unit 1102 is obtained by the exclusive OR circuit 1103b, thereby generating the descrambled DVD data 1113. Every time one data is input to the FIFO unit 1102, the shift register 1103c shifts the data by one bit in it.

Although the seed value is to be originally obtained from the ID information that is transferred into the DVD data 1111 or the DVD data 1112, that ID information which itself might include errors cannot be used.

Accordingly, by setting a sector number which serves as sector ID information that is to be previously transferred by a CPU 1105 in an ID holding register 1104 via a CPU write path 1115, and employing the value of the set sector ID information 1114 as a seed value of the descrambling unit 1103, it is possible to perform descrambling without being affected by incorrect ID information in the DVD data 1111 or the DVD 1112 that might include errors.

Therefore, it is possible to perform data transfer without adversely affecting the correct data including no errors (for example, refer to Patent Document 1).

Patent Document 1: Brochure of International Publication No. 2005/050909

### DISCLOSURE OF THE INVENTION

### Problems to be Solved by the Invention

However, the prior art disclosed in Patent Document 1 has a major premise that the CPU always manages the ID information of the DVD transfer data which are continuously transferred. Therefore, in a system wherein a CPU does not manage ID information or in a system that uses no CPU, if data descrambling is performed with an incorrect seed value, the prior art technique cannot be utilized as a mechanism that does not affect errors.

The present invention is directed to solving the above-described problems and has for its object to provide a data descrambling apparatus and a data descrambling method which can carry out data transfer without adversely affecting correct data including no errors, even when descrambling is carried out using an incorrect seed value in a system wherein a CPU does not manage ID information or a system which is constituted by only such as logic circuits without including a CPU.

### Measure to Solve the Problems

In order to solve the above-described problems, according to Claim 1 of the present invention, there is provided a data descrambling apparatus for performing data descrambling when transferring data including errors, which apparatus comprises an FIFO unit in which data are stored, an error correction unit for receiving data contents from the FIFO unit and performing error detection, an ID holding register for holding a seed that is required for data descrambling or information that is required for seed generation (hereinafter referred to as seed information) when the result of the error detection by the error correction unit is correct data, and a descrambling unit for receiving the data from the FIFO unit and performing descrambling with using a value held in the ID holding register.

According to Claim 2 of the present invention, in the data descrambling apparatus defined in Claim 1, the error correction unit detects presence/absence of an error in the data, and corrects the seed information and stores it in the ID holding register when the error is within a correctable range.

According to Claim 3 of the present invention, in the data descrambling apparatus defined in Claim 2, the error correction unit corrects the seed information and stores it in the ID holding register when the error detection/correction result is uncorrectable and it is within a range that is correctable by a higher-order error correction including transfer data/parity that is used by the error correction unit.

According to Claim 4 of the present invention, in the data descrambling apparatus defined in Claim 1, when an error is detected in the seed information, the error correction unit uses a next ID holding register that is calculated from the previously-used ID holding register.

According to Claim 5 of the present invention, in the data descrambling apparatus defined in Claim 2 or 3, when the error in the seed information is uncorrectable, the error correction unit uses a next ID holding register which is calculated from the previously-used ID holding register.

According to Claim 6 of the present invention, in the data descrambling apparatus defined in Claim 2, when the error correction unit corrects the seed information error and uses the corrected seed information, it transfers the corrected seed information to the FIFO to replace the seed information stored in the FIFO with the corrected seed information.

According to Claim 7 of the present invention, in the data descrambling apparatus defined in Claim 2, when the error correction unit corrects the seed information error and uses the corrected seed information, it transfers the corrected seed information to the buffer memory to replace the seed information stored in the buffer memory with the corrected seed information.

According to Claim 8 of the present invention, in the data descrambling apparatus defined in any of Claims 3 to 5, when the seed information calculated by the ID holding register is used, the corrected seed information is transferred to the FIFO to replace the seed information in the FIFO with the corrected seed information.

According to Claim 9 of the present invention, in the data descrambling apparatus defined in any of Claims 3 to 5, when the seed information calculated by the ID holding register is used, the corrected seed information is transferred to the buffer memory to replace the seed information in the buffer memory with the corrected seed information.

According to Claim 10 of the present invention, the data descrambling apparatus defined in any of Claims 2 to 5, 7 and 9 further includes a seed correction circuit which receives the seed information from the ID holding register, corrects the seed value up to the position of the data being transferred, and outputs the corrected seed value to the descrambling unit.

According to Claim 11 of the present invention, there is provided a data descrambling method for transferring data having a data format in which data scrambling has been performed with a part of the data being a seed value, the data having a possibility of including error data caused by flaws or the like, which method comprises the steps of performing error correction using a first parity code that is generated including the seed value when an error occurs in the seed value, thereby to obtain a correct seed value, and holding data which are obtained by correctly descrambling the data with the correct seed value, on a storage unit.

According to Claim 12 of the present invention, there is provided a data descrambling method for transferring data having a data format in which data scrambling has been performed with a part of the data being a seed value, the data having a possibility of including error data caused by flaws or the like, which method comprises the steps of performing error correction using a first parity code that is generated including the seed value when an error occurs in the seed value, or performing error correction using a second parity code including the seed value and the first parity code when the error correction using the first parity code is not possible, thereby obtaining a correct seed value, and holding the data obtained by correctly descrambling the data with the correct seed value, on a storage unit.

According to Claim 13 of the present invention, the data descrambling method defined in Claim 11 further includes the steps of performing error correction using a seed value that is estimated from the result of the previous data descrambling when the error correction using the first parity code is not possible, and holding data obtained by correctly descrambling the data with the correct seed value, on the storage unit.

According to Claim 14 of the present invention, the data descrambling method defined in Claim 12 further includes the steps of performing error correction using a seed value that is estimated from the result of the previous data descrambling when the error correction using the second parity code is not possible, and holding data obtained by correctly descrambling the data with the correct seed value, on the storage unit.

According to Claim 15 of the present invention, the data descrambling method defined in any of Claims 11 to 14 further includes the step of holding a value that is obtained by correcting the seed value on the storage unit.

### Effects of the Invention

According to the present invention, even when a data descrambling apparatus is an apparatus in which a central processing unit represented by a CPU does not perform management of ID information or seed information, an ID value can be corrected when an error occurs in the seed information during data transfer, and thereby accurate descrambling can be performed. Further, when correction of the ID value is not possible, descrambling can be performed with seed information that is estimated from the previous seed information.

Further, since it is constructed such that the corrected ID value is written back to the main storage unit, it is not necessary to perform error correction again even when rescrambling is required. Further, by writing back the ID value to the FIFO, the rewriting of the ID value can be performed to perform error correction of the ID value without increasing the number of accesses to the main storage unit.

Furthermore, the timing of correcting the seed information is set later than the timing at which the seed information is required, and thereby the amount of data to be stored in the FIFO can be reduced, resulting in a reduction in the circuit scale of the FIFO.

### BRIEF DESCRIPTION OF THE DRAWINGS

FIG. 1(a) is a block diagram illustrating a data descrambling apparatus according to a first embodiment of the present invention.

FIG. 1(b) is a diagram for explaining an ID error detection operation on a DVD data format by the data descrambling apparatus according to the first embodiment of the present invention.

FIG. 1(c) is a flowchart for explaining a control operation of an error detection unit in the data descrambling apparatus according to the first embodiment of the present invention.

FIG. 2(a) is a block diagram illustrating a data descrambling apparatus according to a second embodiment of the present invention.

FIG. 2(b) is a diagram for explaining an ID error detection operation on a DVD data format by the data descrambling apparatus according to the second embodiment of the present invention.

FIG. 2(c) is a flowchart for explaining a control operation of an error detection unit in the data descrambling apparatus according to the second embodiment of the present invention.

FIG. 3(a) is a block diagram illustrating a data descrambling apparatus according to a third embodiment of the present invention.

FIG. 3(b) is a diagram for explaining an ID error detection operation on a DVD data format by the data descrambling apparatus according to the third embodiment of the present invention.

FIG. 3(c) is a flowchart for explaining a control operation of an error detection unit in the data descrambling apparatus according to the third embodiment of the present invention.

FIG. 4(a) is a block diagram illustrating a data descrambling apparatus according to a fourth embodiment of the present invention.

FIG. 4(b) is a flowchart for explaining a control operation of an error detection unit in the data descrambling apparatus according to the fourth embodiment of the present invention.

FIG. 5(a) is a block diagram illustrating a data descrambling apparatus according to a fifth embodiment of the present invention.

FIG. 5(b) is a flowchart for explaining a control operation of an error detection unit in the data descrambling apparatus according to the fifth embodiment of the present invention.

FIG. 6(a) is a block diagram illustrating a data descrambling apparatus according to a sixth embodiment of the present invention.

FIG. 6(b) is a flowchart for explaining a control operation of an error detection unit in the data descrambling apparatus according to the sixth embodiment of the present invention.

FIG. 7 is a diagram illustrating a data format after DVD demodulation according to the sixth embodiment.

FIG. 8 is a diagram illustrating a data format after DVD demodulation.

FIG. 9 is a diagram illustrating a scrambling SEED table.

FIG. 10 is a diagram illustrating a fundamental construction for performing descrambling.

FIG. 11(a) is a block diagram illustrating a conventional data descrambling apparatus.

FIG. 11(b) is a diagram illustrating the construction of a descrambling unit in the conventional data descrambling apparatus.

### DESCRIPTION OF REFERENCE NUMERALS

101 . . . demodulation unit

102 . . . FIFO unit

103 . . . descrambling unit

104 . . . ID holding register

105 . . . error detection unit

106 . . . main storage unit

107 . . . DVD drive

110 . . . readout data

111 . . . demodulated data

112 . . . post-FIFO data

113 . . . descrambled data

114 . . . sector ID information

115 . . . ID information when no error occurs after error detection

116 . . . repetition playback command

117 . . . holding command

122 . . . post-FIFO data

201 . . . demodulation unit

202 . . . FIFO unit

203 . . . descrambling unit

204 . . . ID holding register

205 . . . error correction unit

206 . . . main storage unit

207 . . . DVD drive

210 . . . readout data

211 . . . demodulated data

212 . . . post-FIFO data

213 . . . descrambled data

214 . . . sector ID information

215 . . . ID information after error correction

216 . . . repetition playback command

217 . . . holding command

222 . . . post-FIFO data

301 . . . demodulation unit

302 . . . FIFO unit

303 . . . descrambling unit

304 . . . ID holding register

305 . . . error correction unit 1

306 . . . main storage unit

307 . . . error correction unit 2

308 . . . DVD drive

310 . . . readout data

311 . . . demodulated data

312 . . . post-FIFO data

313 . . . descrambled data

314 . . . sector ID information

315 . . . ID information after error correction

317 . . . ID information after error correction

320 . . . repetition playback command

321 . . . repetition playback command

322 . . . post-FIFO data

323 . . . error detection information

324 . . . holding command

325 . . . holding command

401 . . . demodulation unit

402 . . . FIFO unit

403 . . . descrambling unit

404 . . . ID holding register

405 . . . error detection unit

406 . . . main storage unit

407 . . . DVD drive

408 . . . adder

410 . . . readout data

411 . . . demodulated data

412 . . . post-FIFO data

413 . . . descrambled data

414 . . . sector ID information

415 . . . ID information after error correction

418 . . . estimated ID information

420 . . . playback command

421 . . . addition command

422 . . . post-FIFO data

423 . . . output command

501 . . . demodulation unit

502 . . . FIFO unit

503 . . . descrambling unit

504 . . . ID holding register

505 . . . error detection unit

506 . . . main storage unit

507 . . . DVD drive

510 . . . readout data

511 . . . demodulated data

512 . . . post-FIFO data

513 . . . descrambled data

514 . . . sector ID information

515 . . . ID information after error correction

520 . . . repetition playback command

521 . . . output command

522 . . . post-FIFO data

601 . . . demodulation unit

602 . . . FIFO unit

603 . . . descrambling unit

604 . . . ID holding register

605 . . . error correction unit

606 . . . main storage unit

607 . . . seed correction circuit

608 . . . DVD drive

610 . . . readout data

611 . . . demodulated data

612 . . . post-FIFO data

613 . . . descrambled data

614 . . . sector ID information

615 . . . ID information after error correction

617 . . . seed information after seed correction

620 . . . repetition playback command

621 . . . holding command

622 . . . post-FIFO data

623 . . . seed correction command

701 . . . DVD format ID information

702 . . . DVD format IED information

703 . . . DVD format RSV region

704 . . . DVD format main data region

705 . . . DVD format PI parity information

706 . . . DVD format EDC information

707 . . . DVD format PO parity information

710 . . . burst error portion that occurs due to ID information error

711 . . . data position

801 . . . DVD format ID information

802 . . . DVD format IED information

803 . . . DVD format RSV region

804 . . . DVD format main data region

805 . . . DVD format PI parity information

806 . . . DVD format EDC information

807 . . . DVD format PO parity information

1101 . . . demodulation unit

1102 . . . FIFO unit

1103 . . . descrambling unit

1104 . . . ID holding register

1105 . . . CPU (Central Processing Unit)

1106 . . . main storage unit

1111 . . . demodulated data

1112 . . . post-FIFO data

1113 . . . descrambled data

1114 . . . sector ID information

1115 . . . CPU write path

### BEST MODE TO EXECUTE THE INVENTION

Hereinafter, embodiments of the present invention will be described with reference to the drawings.

### Embodiment 1

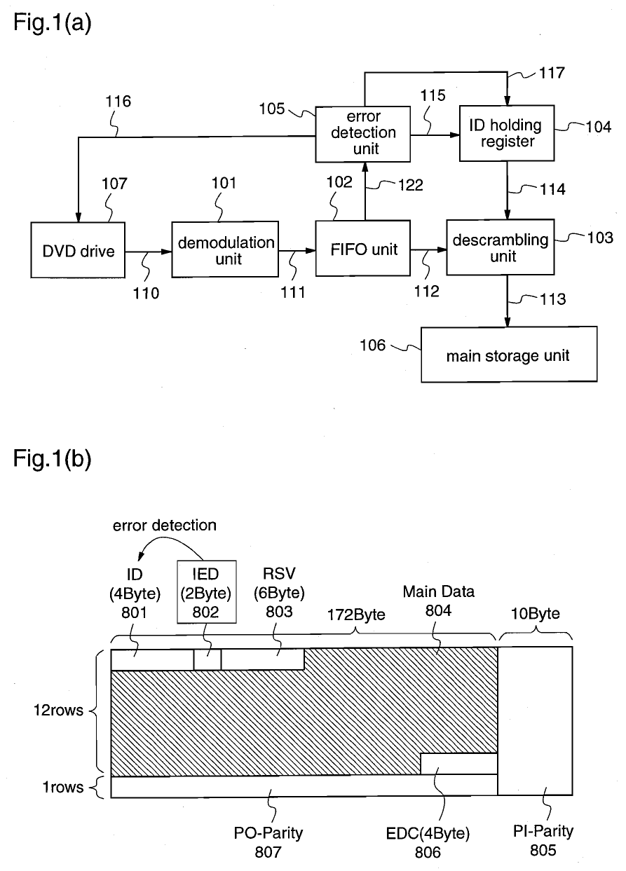

A first embodiment of the present invention is shown in FIG. 1.

FIG. 1(a) shows a data descrambling apparatus according to the first embodiment of the present invention. In FIG. 1(a), 101 denotes a demodulation unit, 102 denotes an FIFO unit, 103 denotes a descrambling unit, 104 denotes an ID holding register, 105 denotes an error detection unit, 106 denotes a main storage unit, and 107 denotes a DVD drive.

FIG. 1(b) is a diagram for explaining an ID error detection operation performed by the data descrambling apparatus according to the first embodiment on a DVD data format.

FIG. 1(c) is a flowchart for explaining the operation of the error detection unit in the data descrambling apparatus according to the first embodiment.

Next, the operation will be described.

When the DVD drive 107 goes into the playback state, demodulated data 111 having the above-described DVD format is output from the demodulation unit 101. The FIFO unit 102 stores the demodulated data 111, and outputs the stored data as post-FIFO data 112 and 122 to the descrambling unit 103 and the error detection unit 105, respectively. The error detection unit 105 performs error detection for ID information 801 in the post-FIFO data 122 by using IED information 802 which is a part of the DVD format in the post-FIFO data 122.

When an error is detected in a part of the ID information that is needed for seed information as a result of the error detection (step 131), the DVD drive 107 performs DVD playback again according to a repetition playback command 116 from the error detection unit 105 (step 132), obtains the same information as readout data 110, and makes the demodulation unit 101 transfer the demodulated data 111. This operation is repeated until no error is detected.

When no error is detected in the ID information part that is needed for seed information as a result of the error detection, ID information 115 which has no error after the error detection is output as the seed information to the ID holding register 104 (step 133). The ID holding register 104 holds the seed information 115 according to a hold command 117 from the error detection unit 105, and forms sector ID information 114 as filter information for performing descrambling, and outputs it to the descrambling unit 103.

The descrambling unit 103 receives the descrambling filter information 114 and the FIFO storage data 112, and execute an EXOR operation of these data to perform descrambling, and thereafter, outputs and stores descrambled data 113 in the main storage unit 106, thereby enabling descrambling of the main data.

The above-described construction enables descrambling in the transferring data including errors, without a CPU intervening.

Further, the operation of the error detection unit shown in FIG. 1(c) can be realized by a simple logic without using a CPU.

As described above, according to the data descrambling apparatus of the first embodiment, since error detection for the ID information is performed using the IED information, correct ID information can be obtained even without a CPU. Thereby, a correct descrambling result can be obtained even in a system constituted without including a CPU or a system in which a CPU does not manage ID information.

While in this first embodiment error detection for the ID information is performed using the IED information, error detection may be performed using information including parity for the ID information, instead of the IED information.

### Embodiment 2

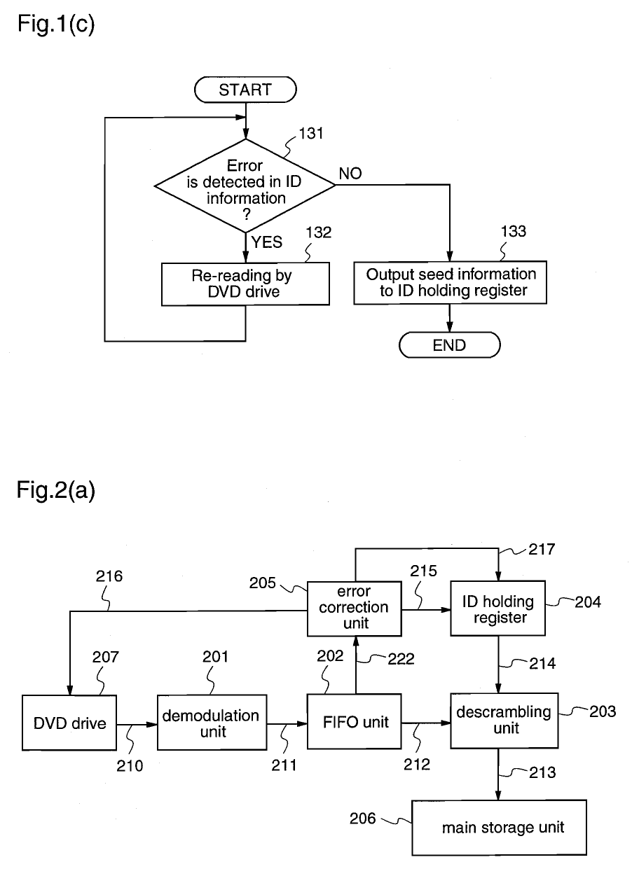

A second embodiment of the present invention is shown in FIG. 2.

FIG. 2(a) shows a data descrambling apparatus according to the second embodiment of the present invention. In FIG. 2(a), 201 denotes a demodulation unit, 202 denotes an FIFO unit, 203 denotes a descrambling unit, 204 denotes an ID holding register, 205 denotes an error correction unit, 206 denotes a main storage unit, and 207 denotes a DVD drive.

FIG. 2(b) is a diagram for explaining ID error detection and correction operations by the data descrambling apparatus according to the second embodiment on a DVD data format.

FIG. 2(c) is a flowchart for explaining the operation of the error correction unit in the data descrambling apparatus according to the second embodiment.

In this second embodiment, the error correction unit 205 is provided instead of the error detection unit 105 of the first embodiment. Accordingly, the other constituents, i.e., the demodulation unit 201, the FIFO unit 202, the descrambling unit 203, the ID holding register 204, and the main storage unit 206 are identical to the demodulation unit 101, the FIFO unit 102, the descrambling unit 103, the ID holding register 104, and the main storage unit 106 of the first embodiment, respectively.

Next, the operation will be described.

The DVD drive 207 outputs readout data 210 according to a playback command 216 from the error detection unit 205, and demodulated data 211 having the above-described DVD format is output from the demodulation unit 201. The FIFO unit 202 stores the demodulated data 211, and outputs post-FIFO data 212 and 222 as the stored data to the descrambling unit 203 and the error correction unit 205, respectively. The error correction unit 205 initially performs error detection for the ID information 801 in the stored data 222 by using IED information 802 that is a part of the DVD format.

As a result of the error detection, when an error is detected in the ID information part that is needed for seed information (step 231) and error correction is possible (step 232), the DVD drive 207 again performs DVD playback according to a repetition playback command 216 from the error detection unit 205 (step 233), obtains the same readout data 210, and makes the demodulation unit 201 transfer the demodulated data 211. This operation is repeated until no error is detected.

As a result of the error detection, when an error is detected in the ID information part that is needed for seed information (step 231) and error correction is possible (step 232), the error correction unit 205 performs error correction, and outputs the error-corrected ID information 215 as the error-corrected seed information to the ID holding register 204 (step 234).

When no error is detected in the ID information part that is needed for seed information, the error correction unit 205 outputs a signal which is equivalent to the seed information obtained from the stored data 222, i.e., a signal which can be regarded as the seed information, to the ID holding register 204 as the seed information (step 235). The ID holding register 204 holds the seed information 215 according to a holding command 217 from the error correction unit 205, forms filter information for descrambling, and outputs the filter information to the descrambling unit 203.

The descrambling unit 203 receives the sector ID information 214 as the descrambling filter information and the FIFO storage data 212, and subjects these data to an EXOR operation to perform descrambling, and thereafter, outputs and stores the descrambled data 213 in the main storage unit 206, thereby realizing descrambling of the main data.

The above-described construction enables descrambling in the transferring data including errors, without a CPU intervening. Further, since the error correction capability is added and thereby the number of times of retransmitting the same information is decreased relative to the first embodiment of the present invention, the time required until the end of transmission can be reduced.

Further, the operation of the error correction unit shown in FIG. 2(c) can be realized by a simple logic without using a CPU.

As described above, according to the data descrambling apparatus of the second embodiment, error detection for the ID information is performed using the IED information, and error correction is performed by the error correction unit when error correction is possible, whereby correct ID information can be obtained even without a CPU. Therefore, a correct descrambling result can be obtained even in a system constituted without including a CPU or a system in which a CPU does not manage ID information.

### Embodiment 3

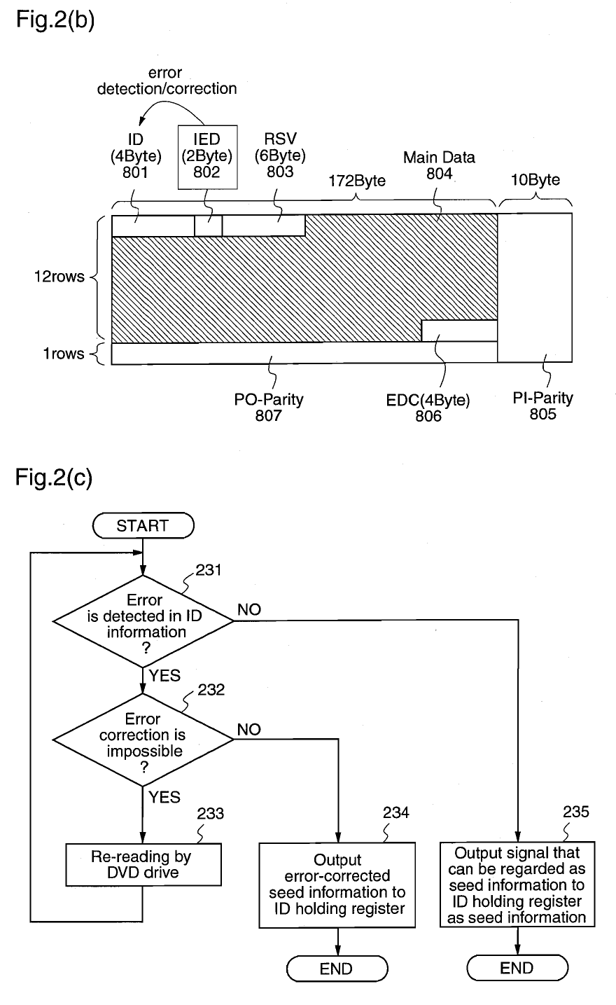

A third embodiment of the present invention is shown in FIG. 3.

FIG. 3(a) shows a data descrambling apparatus according to the third embodiment of the present invention. In FIG. 3(a), 301 denotes a demodulation unit, 302 denotes an FIFO unit, 303 denotes a descrambling unit, 304 denotes an ID holding register, 305 denotes an error correction unit 1, 306 denotes a main storage unit, 307 denotes an error correction unit 2, and 308 denotes a DVD drive.

FIG. 3(b) is a diagram for explaining ID error detection and correction operations by the data descrambling apparatus according to the third embodiment on a DVD data format.

FIG. 3(c) is a flowchart for explaining the operation of the error correction unit in the data descrambling apparatus according to the third embodiment.

This third embodiment adopts two systems of error correction units by adding the error correction unit 2 (307). Accordingly, the other constituents, i.e., the demodulation unit 301, the FIFO unit 302, the descrambling unit 303, the ID holding register 304, the error correction unit 1 (305), and the main storage unit 306 are identical to the demodulation unit 201, the FIFO unit 202, the descrambling unit 203, the ID holding register 204, the error correction unit 205, and the main storage unit 206 according to the second embodiment, respectively.

Next, the operation will be described.

The DVD drive 308 outputs readout data 310 according to a playback command 320 from the error correction unit 1 (305), and the demodulation unit 301 outputs demodulated data 311 having the above-described DVD format. The FIFO unit 302 stores the demodulated data 311, and outputs post-FIFO data 312 and 322 as the stored data to the descrambling unit 303, and the error correction unit 1 (305) and the error correction unit 2 (307), respectively. The error correction unit 1 (305) initially performs error detection for ID information 801 in the stored data 322 with using IED information 802 that is a part of the DVD format.

The error correction unit 2 (307) performs error correction for the ID information 801 in the stored data 322 with using the ID information 801 and the IED information 802 which are parts of the DVD format as well as PI-Parity 805 which is parity information for the RSV information 803 and the main data information 804.

As a result of the error detection, when an error is detected in the ID information part that is needed for the seed information (step 331) and both the error correction unit 1 (305) and the error correction unit 2 (307) cannot correct the error (step 332), (step 333), the DVD drive 308 again performs DVD playback according to repetition playback commands 320 and 321 supplied from the error correction unit 1 (305) and the error correction unit 2 (307), respectively (step 334), and makes the demodulation unit 301 transfer the demodulated data 311 of the same readout data 310, and repeats this operation until no error is detected.

When error detection information 323 from the error correction unit 1 (305) indicates that an error is detected in the ID information part that is needed for the seed information and the error correction unit 1 (305) cannot correct this error, the error-corrected ID information 315 as the error-corrected seed information is output to the ID holding register 304 (step 336), and the ID holding register 304 holds this information according to a holding command 325 from the error correction unit 1 (305). Further, when the error correction unit 1 (305) cannot correct the error but the error correction unit 2 (307) can correct the error, the error-corrected ID information 317 as the error-corrected seed information is output to the ID holding register 304 (step 335), and the ID holding register 304 holds this information according to a holding command 324 from the error correction unit 2 (307).

Further, when no error is detected in the ID information part that is needed for the seed information, the seed information 315 or 317 which is equivalent to the seed information obtained from the stored data 322 is output to the ID holding register 304 (step 337). In this case, since no error correction is performed, either of the seed information 315 and 317 may be adopted.

The ID holding register 304 forms sector ID information 314 as filter information for performing descrambling from the seed information 315, and outputs it to the descrambling unit 303. The descrambling unit 303 receives the descrambling filter information 314 and the post-FIFO data 312 as the FIFO storage data, and performs an EXOR operation of these data to execute descrambling, and thereafter, outputs and stores the descrambled data 313 in the main storage unit 306, thereby realizing descrambling.

The above-described construction enables descrambling in the transferring data including errors, without a CPU intervening. Further, since the error correction capability is enhanced and thereby the number of times of retransmitting the same information is decreased relative to the second embodiment of the present invention, the time required until the end of transmission is reduced.

Further, the operation of the error correction unit shown in FIG. 3(c) can be realized by a simple logic without using a CPU.

As described above, according to the data descrambling apparatus of the third embodiment, error detection for the ID information is performed using the IED information, and error correction is performed when error correction is possible, while error correction is performed using the PI-Parity when error correction is impossible, whereby correct ID information can be obtained even without a CPU. Therefore, a correct descrambling result can be obtained even in a system constituted without including a CPU and a system in which a CPU does not manage ID information.

### Embodiment 4

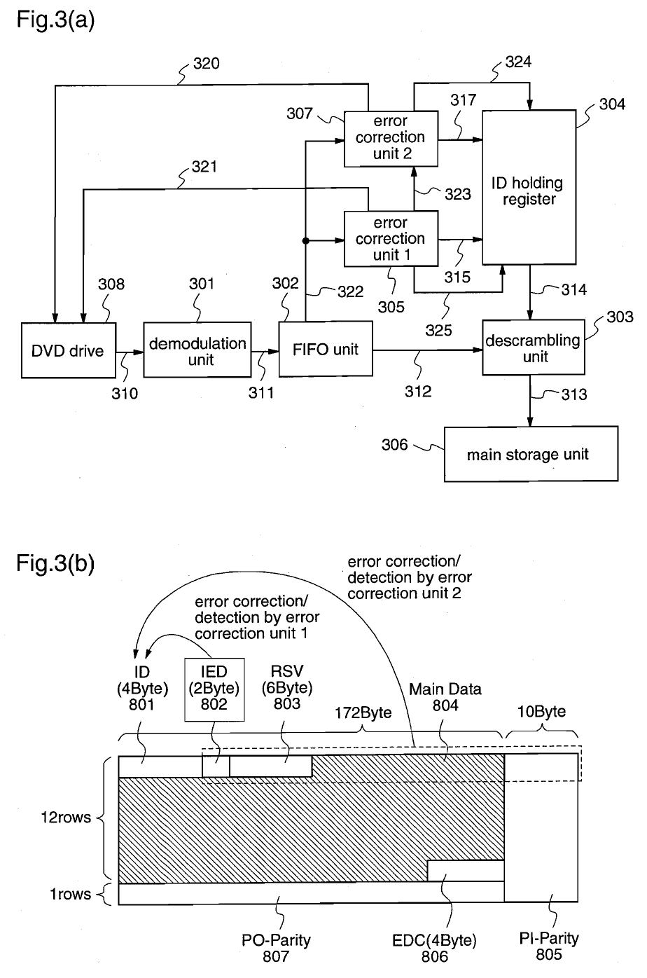

A fourth embodiment of the present invention is shown in FIG. 4.

FIG. 4(a) shows a data descrambling apparatus according to the fourth embodiment of the present invention. In FIG. 4(a), 401 denotes a demodulation unit, 402 denotes an FIFO unit, 403 denotes a descrambling unit, 404 denotes an ID holding register, 405 denotes an error detection unit, 406 denotes a main storage unit, 407 denotes a DVD drive, and 408 denotes an adder.

FIG. 4(b) is a flowchart for explaining the operation of the error detection unit in the data descrambling apparatus according to the fourth embodiment.

A diagram for explaining an ID error detection operation according to the fourth embodiment on the DVD data format is identical to FIG. 1(b).

This fourth embodiment is obtained by adding the adder 408 to the first embodiment. Accordingly, the other constituents, i.e., the demodulation unit 401, the FIFO unit 402, the descrambling unit 403, the ID holding register 404, the error detection unit 405, and the main storage unit 406 are identical to the demodulation unit 101, the FIFO unit 102, the descrambling unit 103, the ID holding register 104, the error detection unit 105, and the main storage unit 106 according to the first embodiment, respectively.

Next, the operation will be described. The DVD drive 407 outputs readout data 410 according to a playback command 420 from the error detection unit 405, and the demodulation unit 401 outputs the demodulated data 411 having the above-described DVD format.

The FIFO unit 402 stores the demodulated data 411, and outputs the stored data 412 and 422 as post-FIFO data 412 and 422 to the descrambling unit 403 and the error detection unit 405, respectively. The error detection unit 405 performs error detection for the ID information 801 in the stored data 422 with using IED information 802 that is a part of the DVD format (step 431).

When an error is detected in the ID information part that is needed for the seed information as a result of the error detection, the error detection unit 405 inputs the previous seed information 414 that is stored in the ID holding register 404 to the adder 408 according to an output command 423 (step 432), and a value which is obtained by adding “1” to the ID holding register 404 by the adder 408 according to an addition command 421 is output as an output result, i.e., expected ID information 418 (step 433).

Sector numbers are described as data in the ID information used as the seed information, and usually, values each incremented by “1” are stored. Accordingly, it is expected that a value obtained by adding “1” to the previous sector is the sector number of the current sector.

When no error is detected in the ID information part that is needed for the seed information as a result of the error detection, the seed information, i.e., the error-corrected ID information 415, is output to the ID holding register 404 (step 434).

The ID holding register 404 selects the seed information 415 and 418 according to the result of the error detection, and outputs filter information for performing descrambling from the seed information 415 to the descrambling unit 403. The descrambling unit 403 receives the sector ID information 414 as the descrambling filter information and the post-FIFO data 412, and executes an EXOR operation to perform descrambling, and thereafter, outputs and stores the descrambled data 413 into the main storage unit 406, thereby realizing descrambling.

The operation of the error correction unit shown in FIG. 4(b) can be realized by a simple logic without using a CPU.

As described above, according to the data descrambling apparatus of the fourth embodiment, since error detection for the ID information is performed using the IED information, correct ID information can be obtained even without a CPU. Thereby, a correct descrambling result for the transferring data including errors can be obtained even in a system constituted without including a CPU and a system in which a CPU does not manage ID information.

Further, when an error is detected, a value obtained by adding “1” to the value which has previously been stored in the ID holding register is used as a sector number, it is not necessary to transmit the same information again, and thereby the time until the end of transmission can be reduced.

The construction of using, as a sector number, a value which is obtained by adding “1” to the value that has previously been stored in the ID holding register by the adder according to this fourth embodiment can be similarly executed in the second or third embodiment.

### Embodiment 5

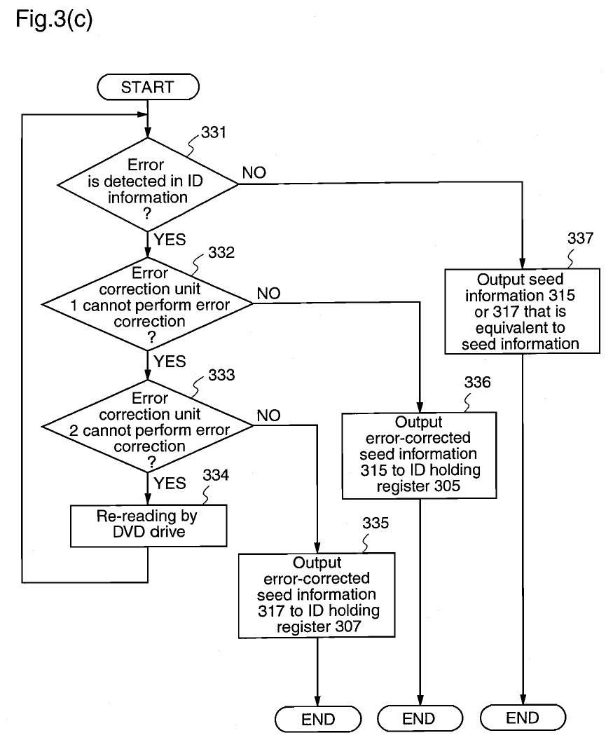

A fifth embodiment of the present invention is shown in FIG. 5.

FIG. 5(a) shows a data descrambling apparatus according to the fifth embodiment of the present invention. In FIG. 5(a), 501 denotes a demodulation unit, 502 denotes an FIFO unit, 503 denotes a descrambling unit, 504 denotes an ID holding register, 505 denotes an error correction unit, 506 denotes a main storage unit, and 507 denotes a DVD drive.

FIG. 5(b) is a flowchart for explaining the operation of the error correction unit in the data descrambling apparatus according to the fifth embodiment.

A diagram for explaining ID error detection and correction operations according to the fifth embodiment on the DVD data format is identical to FIG. 2(b).

The fifth embodiment has the same block construction as that of the second embodiment, and it is constituted such that the output of the ID holding register is directly input to the main storage unit.

Next, the operation will be described. The DVD drive 507 outputs readout data 510 according to a playback command 520 from the error correction unit 505, and the demodulation unit 501 outputs demodulated data 511 having the above-described DVD format. The FIFO unit 502 stores the demodulated data 511, and outputs post-FIFO data 512 and 522 as the stored data to the descrambling unit 503 and the error correction unit 505, respectively. The error correction unit 505 initially performs error detection for ID information 801 in the stored data 522 with using IED information 802 that is a part of the DVD format.

As a result of the error detection, when an error is detected in the ID information part that is needed for seed information (step 531) and error correction is not possible (step 532), the error correction unit 505 makes the DVD drive 507 perform DVD playback again according to a repetition playback command 520 (step 533), and makes the demodulation unit 501 transfer the readout data 510 of the same information, and repeats this operation until no error is detected.

As a result of the error detection, when an error is detected in the ID information part that is needed for seed information and error correction is possible, the error correction unit 505 outputs the error-corrected ID information 515 as the error-corrected seed information to the ID holding register 504 (step 534). Further, when no error is detected in the ID information part that is needed for seed information, a signal which is equivalent to the seed information obtained from the stored data 522 is output as seed information 515 to the ID holding register 504 (step 535).

The ID holding register 504 forms filter information for performing descrambling from the seed information 515, and outputs it to the descrambling unit 503. Further, the ID holding register 504 outputs correct ID information 514 to the main storage unit according to an output command 521 from the error correction unit 505 (step 536), thereby to replace the ID information on the main storage unit.

The descrambling unit 503 receives the sector ID information 514 as the descrambling filter information and the FIFO storage data 512, and performs an EXOR operation of these data to perform descrambling, and thereafter, outputs and stores the descrambled data 513 in the main storage unit 506, thereby realizing descrambling.

The operation of the error correction unit shown in FIG. 5(b) can be realized by a simple logic without using a CPU.

As described above, according to the data descrambling apparatus of the fifth embodiment, error detection for the ID information is performed using the IED information, and error correction is performed by the error correction unit when error correction is possible, whereby correct ID information can be obtained even without a CPU. Therefore, a correct descrambling result can be obtained even in a system constituted without including a CPU or a system in which a CPU does not manage ID information.

Further, since the correct ID information is left on the main storage unit after the end of transfer, it is not necessary to perform error correction again if descrambling is again performed in the subsequent processing.

The construction of inputting the output of the ID holding register directly to the main storage unit according to this fifth embodiment can be similarly executed also in the third and fourth embodiments.

While in this fifth embodiment rewriting of the ID value to the correct ID value stored in the ID holding register 504 is performed in the main storage unit 706, this rewriting may be performed in the FIFO unit 502, which is advantageous over the case of performing the rewriting in the main storage unit 706, because the number of accesses to the main storage unit is not increased.

### Embodiment 6

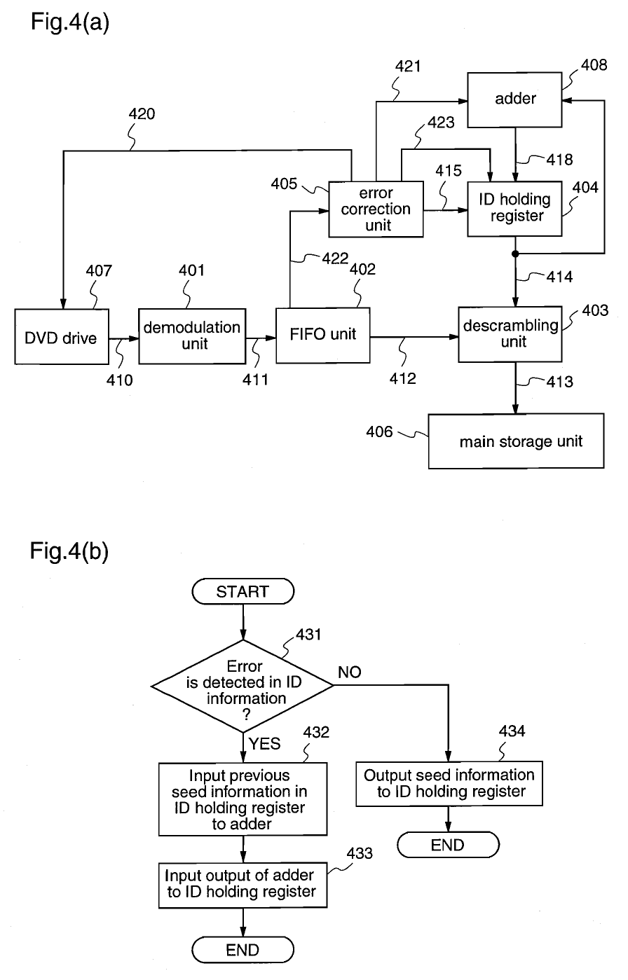

A sixth embodiment of the present invention is shown in FIG. 6.

FIG. 6(a) shows a data descrambling apparatus according to the sixth embodiment of the present invention. In FIG. 6(a), 601 denotes a demodulation unit, 602 denotes an FIFO unit, 603 denotes a descrambling unit, 604 denotes an ID holding register, 605 denotes an error correction unit, 606 denotes a main storage unit, 607 denotes a seed correction circuit, and 608 denotes a DVD drive.

FIG. 6(b) is a flowchart for explaining the operation of the error correction unit in the data descrambling apparatus according to the sixth embodiment.

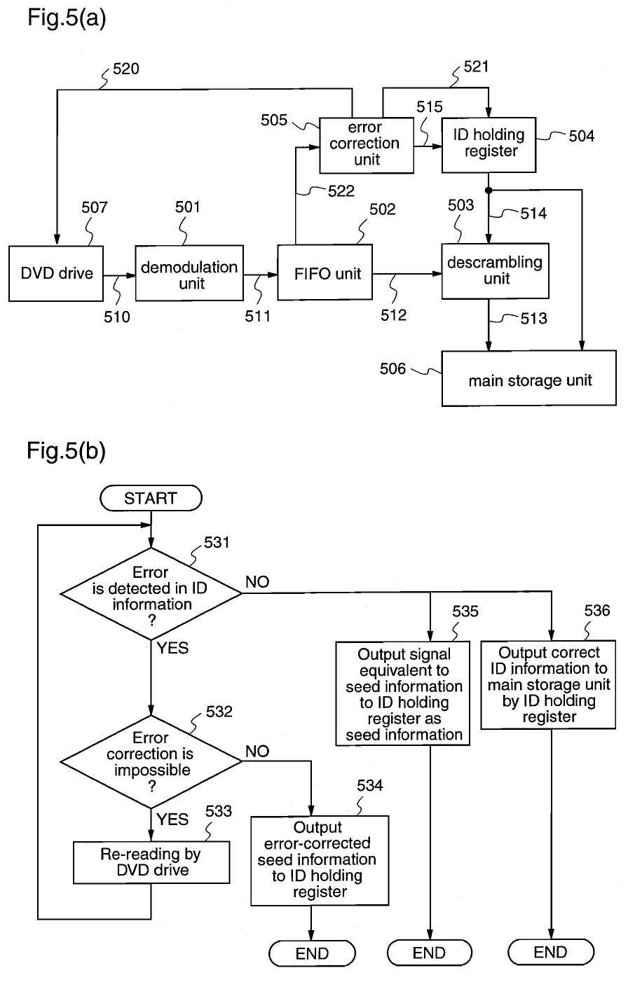

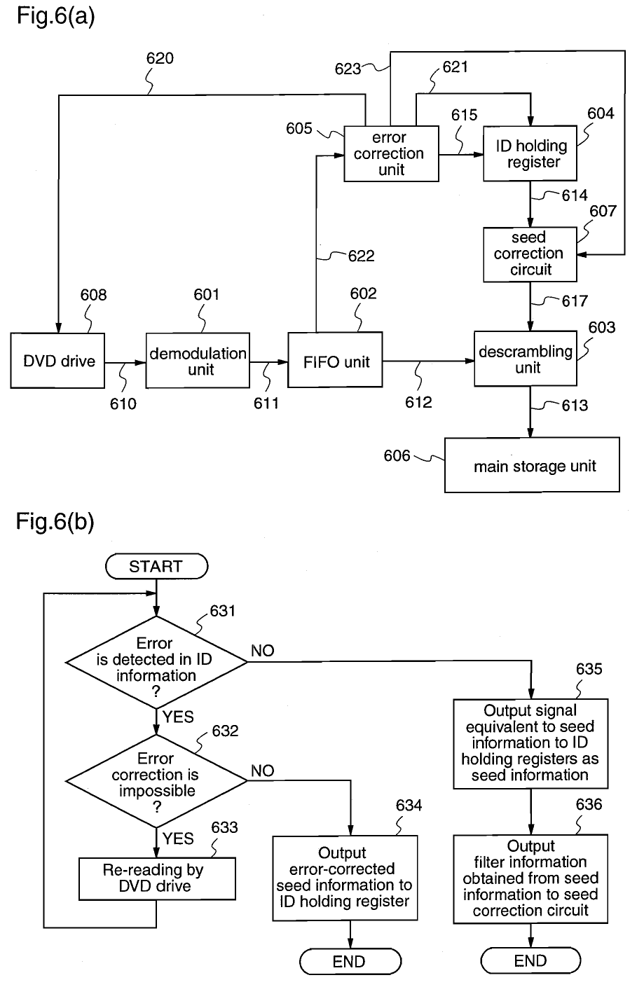

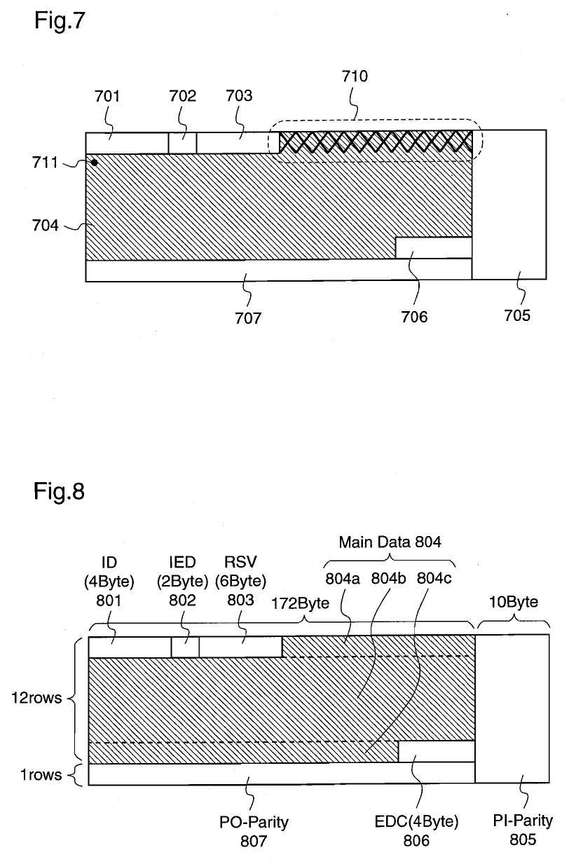

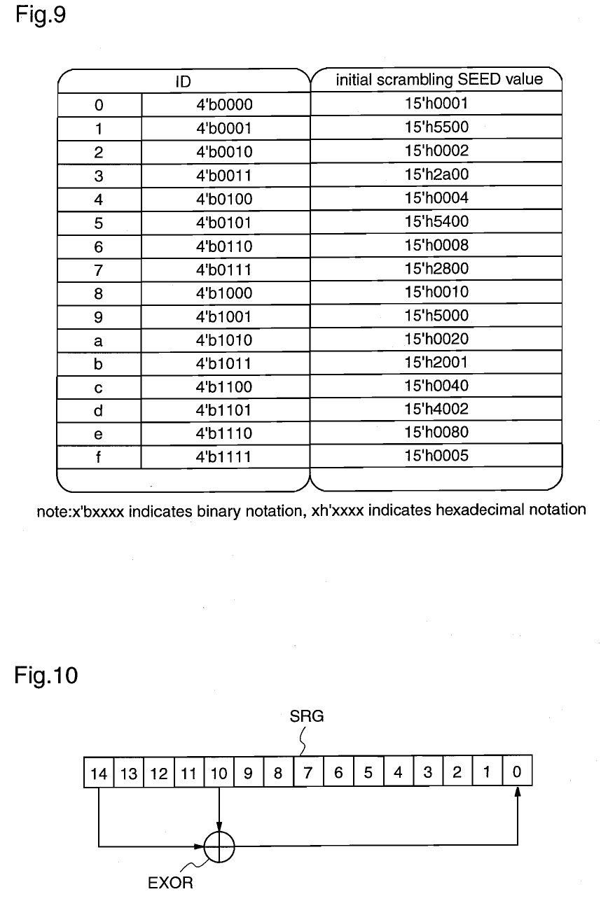

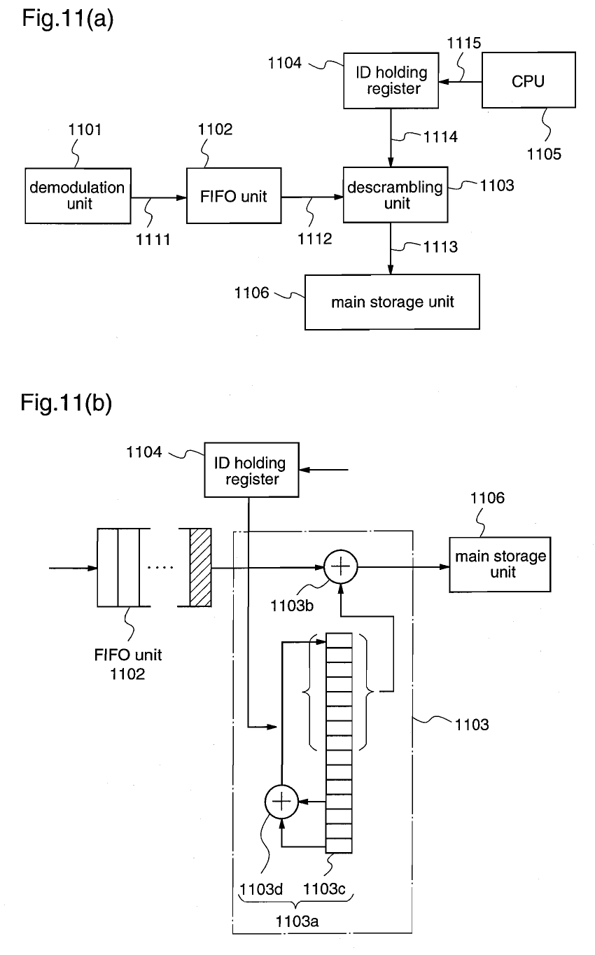

FIG. 7 is a diagram schematically illustrating, on the DVD format, the function of the seed correction unit in the data descrambling apparatus according to the sixth embodiment.

The DVD drive 608 outputs readout data 610 according to a playback command 620 from the error correction unit 605, and the demodulation unit 601 outputs demodulated data 611 having the above-described DVD format. The FIFO unit 602 stores the demodulated data 611. It is assumed that the storage capacity of the FIFO unit 602 is 4 bytes. The post-FIFO data 612 and 622 as the stored data are output to the descrambling unit 603 and the error correction unit 605, respectively.

The error correction unit 605 initially performs error detection for ID information 701 in the stored data 622 with using the ID information 701, the IED information 702, and the RSV information 703 which are parts of the DVD format, and the PI parity information 705 as parity information for the data information 704.

As a result of the error detection, when an error is detected in the ID information part that is needed for the seed information (step 631) and error correction is not possible (step 632), the error correction unit 605 makes the DVD drive 608 perform DVD playback again according to a repetition playback command 620 (step 633), and makes the demodulation unit 601 transfer the readout data 610 of the same information, and repeats this operation until no error is detected.

As a result of the error detection, when an error is detected in the ID information part that is needed for the seed information and error detection is possible, the error correction unit 605 outputs the error-corrected ID information 615 as the error-corrected seed information to the ID holding register 604 (step 634). Further, when no error is detected in the ID information part that is needed for the seed information, a signal equivalent to the seed information obtained from the stored data 622 is output as seed information 615 to the ID holding register 604 (step 635).

The ID holding register 604 holds the seed information 615 according to a holding command 621 from the error correction unit 605, and forms sector ID information 614 as filter information for performing descrambling from the seed information 615, and outputs it to the seed correction circuit 607 (step 636).

As for the data storage capacity of the FIFO unit 602, 182 bytes comprising 4 bytes of the ID 701+2 bytes of the IED 702+6 bytes of the RSV 703+160 bytes of the part of the main data 704+10 bytes of the PI-Parity 705 are required in order to accurately perform error correction. However, since the storage capacity is set to 4 bytes as described above to reduce the circuit scale of the FIFO unit 602, these data have already been stored in the main storage unit 606 at the timing when the correct seed value i s obtained.

Therefore, a data region 710 wherein garbled data, i.e., missing of data, occurs due to the incorrect seed is generated in a part of the main data 704. So, the seed correction circuit 607 calculates a data position 711 which is advanced by 160 bytes (=172−12) corresponding to the byte length of a burst error part 710 as a data region that occurs due to the ID information error, according to a seed correction command 623 from the error correction unit 605, and outputs the same to the descrambling unit 603. This data position 711 is located at the beginning of the second row of the main data 704 shown in FIG. 7.

The descrambling unit 603 receives the descrambling filter information 614 and the FIFO storage data 612, and performs an EXOR operation from the data position 711 located at the beginning of the second row of the main data 704 shown in FIG. 7 to execute descrambling, and thereafter, outputs and stores the descrambled data 613 in the main storage unit 606, thereby realizing descrambling.

On the other hand, the data region 710 wherein garbled data, i.e., missing of data, occurs is within the range of correction capability by another error correction such as PO parity, and it can be returned to the correct data by another error correction, and therefore, no problem occurs.

The above-described construction enables descrambling in the transferring data including errors, without a CPU intervening.

As described above, according to the data descrambling apparatus of the sixth embodiment, since error detection for the ID information is performed using the IED information and error correction is performed by the error correction unit when error correction is possible, whereby correct ID information can be obtained even without a CPU. Therefore, a correct descrambling result can be obtained even in a system constituted without including a CPU and a system in which a CPU does not manage ID information.

Further, since the seed value is corrected so that the seed value matches the position of the data being transferred, the storage capacity of the FIFO can be reduced, and a significant reduction in circuit scale can be achieved in a system having a large amount of data including data regions and parities.

While in the respective embodiments described above the scrambled data are read out from the DVD by the DVD drive, the data may be obtained from other information sources with the same effects as mentioned above.

### APPLICABILITY IN INDUSTRY

The present invention is widely applicable to systems such as optical discs, which perform data descrambling during transfer of data that include errors and can be subjected to error detection/correction by parities.

1. A data descrambling apparatus for performing data descrambling when transferring data including errors, comprising:
an FIFO unit in which data are stored;
an error correction unit for receiving data contents from the FIFO unit and performing error detection;
an ID holding register for holding a seed that is required for data descrambling or information that is required for seed generation (hereinafter referred to as seed information) when the result of the error detection by the error correction unit is correct data; and
a descrambling unit for receiving the data from the FIFO unit and performing descrambling with using the value held in the ID holding register.

2. A data descrambling apparatus as defined in claim 1 wherein
said error correction unit detects presence/absence of an error in the data, and corrects the seed information and stores it in the ID holding register when the error is within a correctable range.

3. A data descrambling apparatus as defined in claim 2 wherein
said error correction unit corrects the seed information and stores it in the ID holding register when the error detection/correction result is uncorrectable and it is within a range that is correctable by a higher-order error correction including transfer data/parity that is used by the error correction unit.

4. A data descrambling apparatus as defined in claim 1 wherein
when an error is detected in the seed information, said error correction unit uses a next ID holding register which is calculated from the previously-used ID holding register.

5. A data descrambling apparatus as defined in claim 2 wherein
when the error in the seed information is uncorrectable, said error correction unit uses a next ID holding register which is calculated from the previously-used ID holding register.

6. A data descrambling apparatus as defined in claim 2 wherein
when said error correction unit corrects the seed information error and uses the corrected seed information, it transfers the corrected seed information to the FIFO unit to replace the seed information stored in the FIFO unit with the corrected seed information.

7. (canceled)

8. A data descrambling apparatus as defined in claim 3 wherein
when the seed information calculated by the ID holding register is used, the corrected seed information is transferred to the FIFO unit to replace the seed information in the FIFO unit with the corrected seed information.

9. (canceled)

10. A data descrambling apparatus as defined in claim 2 further including a seed correction circuit which receives the seed information from the ID holding register, corrects the seed value up to the position of the data being transferred, and outputs the corrected seed value to the descrambling unit.

11. A data descrambling method for transferring data having a data format in which data scrambling has been performed with a part of the data being a seed value, said data having a possibility of including error data caused by flaws or the like, said method comprising the steps of:
performing error correction using a first parity code that is generated including the seed value when an error occurs in the seed value, thereby to obtain a correct seed value; and
holding data which are obtained by correctly descrambling the data with the correct seed value, on a storage unit.

12. A data descrambling method for transferring data having a data format in which data scrambling has been performed with a part of the data being a seed value, said data having a possibility of including error data caused by flaws or the like, said method comprising the steps of:
performing error correction using a first parity code that is generated including the seed value when an error occurs in the seed value, or performing error correction using a second parity code including the seed value and the first parity code when the error correction using the first parity code is not possible, thereby obtaining a correct seed value; and
holding the data obtained by correctly descrambling the data with the correct seed value, on a storage unit.

13. A data descrambling method as defined in claim 11 further including the steps of:
performing error correction using a seed value that is estimated from the result of the previous data descrambling when the error correction using the first parity code is not possible; and
holding data obtained by correctly descrambling the data with the correct seed value, on the storage unit.

14. A data descrambling method as defined in claim 12 further including the steps of:
performing error correction using a seed value that is estimated from the result of the previous data descrambling when the error correction using the second parity code is not possible; and
holding data obtained by correctly descrambling the data with the correct seed value, on the storage unit.

15. A data descrambling method as defined in claim 11 further including the step of holding a value that is obtained by correcting the seed value on the storage unit.

16. A data descrambling apparatus as defined in claim 4 wherein
When the seed information calculated by the ID holding register is used, the corrected seed information is transferred to the FIFO unit to replace the seed information in the FIFO unit with the corrected seed information.

17. A data descrambling apparatus as defined in claim 5 wherein
When the seed information calculated by the ID holding register is used, the corrected seed information is transferred to the FIFO unit to replace the seed information in the FIFO unit with the corrected seed information.

18. A data descrambling apparatus as defined in claim 4 further including a seed correction circuit which receives the seed information from the ID holding register, corrects the seed value up to the position of the data being transferred, and outputs the corrected seed value to the descrambling unit.

19. A data descrambling method as defined in claim 12 further including the step of holding a value that is obtained by correcting the seed value on the storage unit.
